(19) United States
(12) Patent Application Publication
(10) Pub. No.: US 2017/0287768 A1
(43) Pub. Date: Oct. 5, 2017

(54) Apparatus and Method to Improve Plasma Dicing and Backmetal Cleaving Process

(71) Applicant: VEECO PRECISION SURFACE PROCESSING LLC, Horsham, PA (US)

(72) Inventors: Laura Mauer, South Kent, CT (US); John Taddei, Jim Thorpe, PA (US); Kenji Nulman, Warminster, PA (US); Lev Rapoport, Yardley, PA (US); John Clark, Philadelphia, PA (US)

(21) Appl. No.: 15/472,931

(22) Filed: Mar. 29, 2017

Related U.S. Application Data
(60) Provisional application No. 62/314,752, filed on Mar. 29, 2016.

(51) Int. Cl. H01L 21/687; H01L 21/683; H01L 21/67

(52) U.S. Cl. CPC H01L 21/68735; H01L 21/67092; H01L 21/6836

(57) ABSTRACT

An apparatus and method to improve the plasma dicing and backmetal cleaving process on substrates through the use of pressurized deionized water (DI) dispense and specialized tooling.

### CROSS REFERENCE TO RELATED APPLICATION

The present application claims priority to U.S. patent application Ser. No. 62/314,752, filed Mar. 29, 2016, which is hereby incorporated by reference in its entirety.

### TECHNICAL FIELD

The present embodiment generally relates to an apparatus and method for improving the plasma dicing and backmetal cleaving process. More specifically, it relates to an apparatus and method that employs a pressurized DI spray to cleave metal films on semiconductor substrates post plasma dicing. Specializing tooling permits the spray to contact the full substrate surface and dampens the pressurized stream force to permit cleaving to take place without damage to the metal or die, or to prematurely remove die off the adhesive material.

### BACKGROUND

The semiconductor industry historically manufactured devices on substrates. In many cases these were wafers. The devices on the wafers were manufactured in a re-occurring die pattern across the wafer surface. When manufacturing was completed, the die needed to be separated in order to mount them. A common method utilized was to mount the entire substrate on an adhesive film somewhat larger than the wafer. The film was then terminated on a saw frame, a metal piece that kept the adhesive tape pulled to a prescribed tension. The mounted wafer then had the die cut apart through the use of a dicing saw that typically removed a width of 80 micron between the die. Subsequently the adhesive film could be stretched to separate the die and the die could be removed individually and mounted in the final packaging.

Progress was made when plasma dicing replaced the saw. This technique removed as little as 10 micron between die, which permitted more die to be manufactured on a wafer. This technique offered other advantages, such as higher throughputs through the dicing step. One limitation of plasma dicing was the selective etch between substrate material and other films found on semiconductor substrates. Films, such as oxides, polyimide and metals, have selectivity with the plasma >500:1 as compared to silicon. Accordingly, these films were left intact when the plasma dicing process was complete. Essentially the die were diced but remained held together by the backmetal. Thin metal films (<0.2 micron) could potentially be separated stretching the adhesive tape with the metal intact. However many applications found in LED, MEMS and power devices have a thick backside metal layer (such as 1-3 micron or more of gold, silver or other metals). Backmetal this thick cannot be cleanly pulled apart by stretching the adhesive tape the substrate is mounted on. An alternative method to cleave the backmetal along the plasma dice path was required in order to remove the die without damage. Early attempts to use a water spray to cleave the backmetal were not able to obtain a clean and total cleave without damaging die or losing die off the adhesive film.

### BRIEF DESCRIPTION OF THE DRAWING FIGURES

FIG. 1 is a top plan view of a tool in accordance with one embodiment of the present invention;

FIG. 2 is a side elevation view of the tool of FIG. 1;

FIG. 3 is a cross-sectional view taken along the line A-A of FIG. 1;

FIG. 4 is an exploded perspective view of a chuck assembly;

FIG. 5 is an exploded perspective view of a saw frame containing a wafer and the chuck assembly;

FIG. 6 is an exploded perspective view of a chuck assembly according to another embodiment of the present invention showing a support pad exploded from the chuck assembly; and

FIG. 7 is a perspective view of the chuck assembly of FIG. 6 with the support pad attached thereto.

### DETAILED DESCRIPTION OF CERTAIN EMBODIMENTS

The embodiment is comprised of one or more wet processing chambers. Example wet processing systems are disclosed in U.S. patent application Ser. No. 13/780,657 filed on Feb. 28, 2013 and entitled “System and Method for Performing a Wet Etching Process”, U.S. patent application Ser. No. 13/922,735 filed on Jun. 20, 2013 and entitled “Apparatus and Method for Challenging Polymer Films and Structures from Semiconductor Wafers”, U.S. patent application Ser. No. 11/640,044 filed on Dec. 15, 2006 and entitled “Apparatus and Method of Chemical Separation”, U.S. patent application Ser. No. 14/457,645 filed on Aug. 12, 2014 and entitled “Collection Chamber Apparatus to Separate Multiple Fluids During the Semiconductor Wafer Processing Cycle”, and U.S. patent application Ser. No. 09/841,231 filed on Apr. 24, 2001 and entitled “Megasonic Treatment Apparatus”, all of which are incorporated by reference herein in their entirety. Substrates mounted to adhesive film within a dicing frame are processed while held and supported by a spin chuck. The mounting can be metal side up or down. One non limiting example of a suitable substrate is disclosed in U.S. patent application Ser. No. 14/034,164 filed on Sep. 23, 2013 and entitled “Method for Dicing a Substrate with Back Metal”, which is incorporated by reference herein in its entirety. There may be adhesive on the bottom side but there may also be a second piece of adhesive on the substrate topside. While the substrate spins a DI water spray contacts the face up side of the substrate. Pressured DI can be applied from a variety of nozzle types, pressures, heights and angles of contact. The purpose of the water dispense is to flex die in order to cleanly cleave the metal film along the plasma dice line. The thinnest of metal layers can be cleaved with light pressure (<100 PSI). Thick metal films require high pressure (thousands of PSI) applied at specific heights and angles. The embodiment incorporates recipe driven pressure control, nozzle selection, nozzle height, arm scan motion (speed, acceleration) chuck rpm control. To obtain the metal cleave with no damage or lost die, a hard support surface under the wafer will not work.

Accordingly, a material with specific properties that provides support but is sufficiently elastic to flex the die to permit metal cleaving without de-bonding to the adhesive film is required and the present invention addresses and a solution for this need. At the end of the process, the saw frame 310 is spun at higher rpm to dry everything prior to removal from the process chamber. At this point the metal has been cleaved and the substrate can go on to traditional die removal and die mounting sequences.

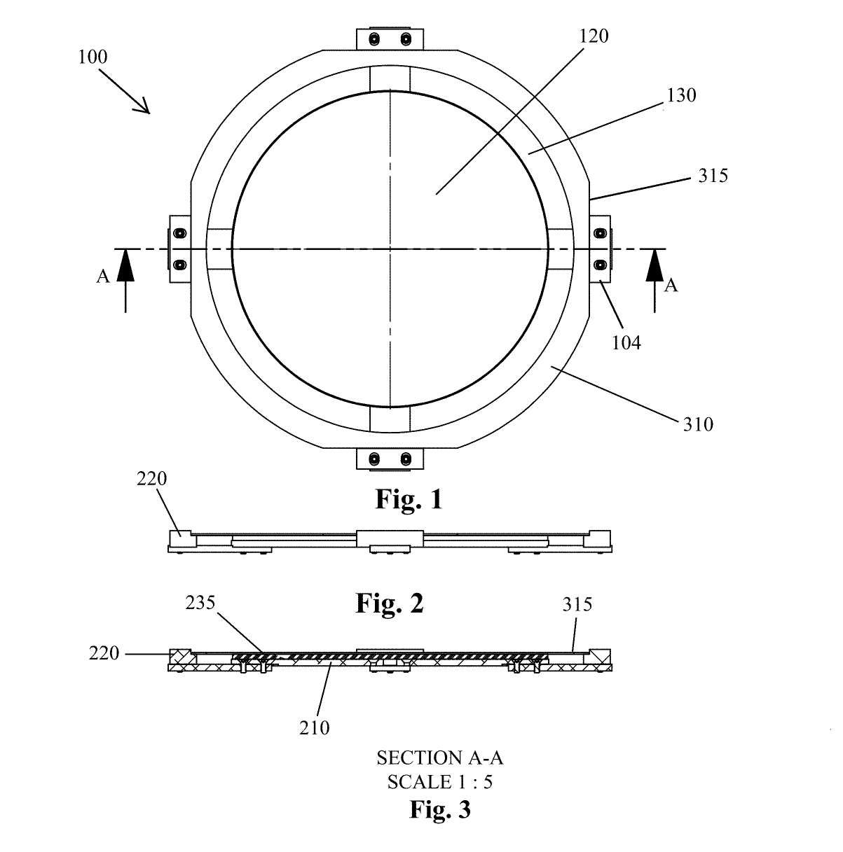

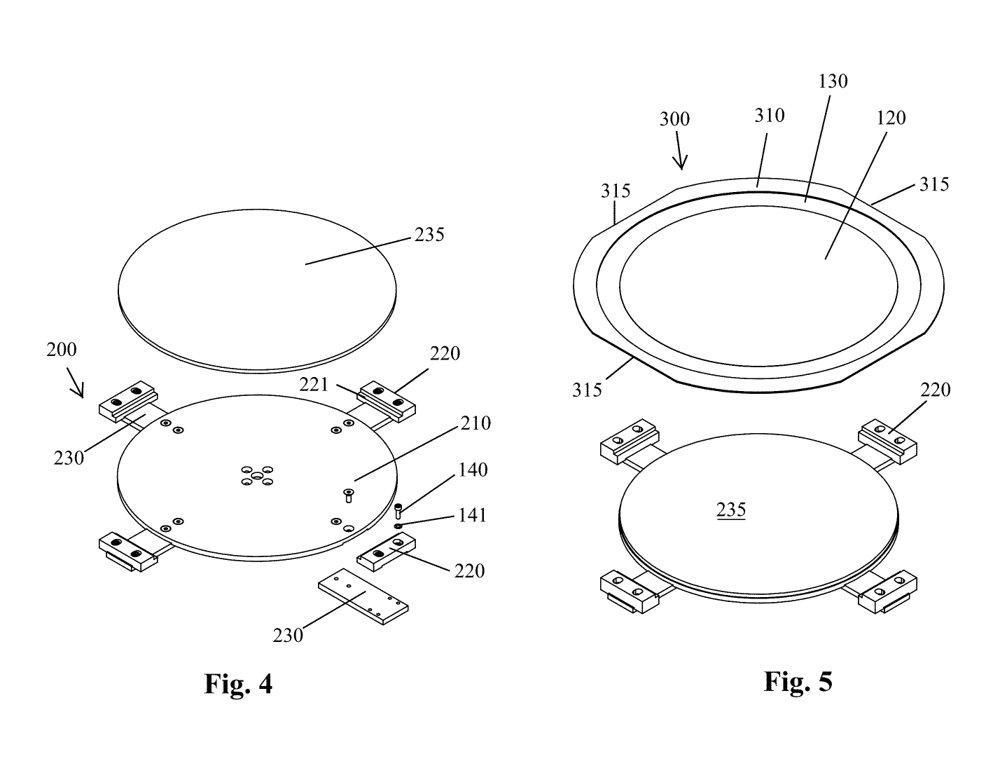

Referring to FIGS. 1-5, a tool (system) 100 is provided and generally is formed of a chuck assembly 200 and a saw frame assembly 300. As discussed herein, the saw frame assembly 300 is configured to support and carry a substrate (wafer) 120 and interlockingly mates with the chuck assembly 200 in such a way that the saw frame assembly 300 can be easily interlocked with the chuck assembly 200 and detached therefrom after the process is completed. The interlocking between the saw frame assembly 300 and the chuck assembly 200 can be of an active type in which an interlocking member (not shown) connects the two to one another or, as illustrated, can be of a passive nature in which a mechanical fit (e.g., friction fit) can be provided and serves to hold the saw frame assembly 300 in place relative to the chuck assembly 200.

The substrate (wafer) 120 is mounted to an adhesive film 130 within a saw frame 310. In particular, the adhesive film 130 serves to adhesively mount the substrate 120 to a top surface of the saw frame 310. As will be understood by one skilled in the art, the saw frame 310 comprises an annular shaped structure with a center hole formed therein over which the substrate 120 is mounted. The adhesive film 130 serves to attach the substrate 120 to the saw frame 310 under appropriate tension. The saw frame 310 can be formed of any number of different materials, such as metal, etc. The saw frame 310 can take any number of different shapes and size. The saw frame 310 includes at least one and preferably a plurality of locking edges 315 that are formed along an outer periphery thereof. In the illustrated embodiment, each locking edge 315 is in the form of flat in that each is a planar edge formed in what is otherwise a curved outer periphery. As illustrated, there are four locking edges 315 are formed as two opposing pairs of locking edges, namely, the locking edges 315 are located at the 12 o'clock; 3 o'clock; 6 o'clock; and 9 o'clock positions.

Since the substrate 120 is positioned over the center hole of the saw frame 310, the substrate 120 can flex if a sufficient force is applied thereto.

The tool has the ability for substrates 120 mounted to the adhesive film 130 within the saw frame 310 to be loaded individually or as a lot within a cassette. Cassette loaded tools require a robot to transfer the substrates 120 to the processing chamber. There the substrate 120 will be held in place by specialized tooling called a spin chuck body 210 of the assembly 200. On manual load tools, the operator places the dicing saw frame 310 directly on to the spin chuck body 210.

The spin chuck body 210 is typically a disk shaped structure as shown. The chuck body 210 has a peripheral (circumferential) edge. The spin chuck assembly 200 also includes at least one and preferably a plurality of retainers 220 that are configured to hold the saw frame assembly 300 in place. As illustrated, the retainers 220 can be spaced radially outward from the peripheral edge of the chuck body 210. Each retainer 220 has a shoulder 221 that is configured to seat against one locking edge 315 of the saw frame 310. The shoulder 221 is thus formed in a planar manner in retainer 220 which resembles a block which is mounted radially outward from the peripheral edge. The retainer 220 can be fixedly connected to the chuck body 210 with an arm structure 230. At one end, the arm 230 is mounted to an underside of the chuck body 210 (e.g., as by using fasteners 40) and the retainer (block) 220 is mounted to the other end of the arm 230 (as by using fasteners 40, 41). The arm 230 can include different sets of openings for receiving fasteners 40, thereby allowing the retainer 220 to be mounted to the arm 230 in one of a plurality of different radial positions relative to the chuck body 210. In other words, the radial distance of the retainer 220 can be selected in view of the size of the saw frame 310, etc. As shown, the retainers 220 are elevated relative to the arms 230.

The retainers 220 are thus placed in locations that mate with the locking edges 315 and therefore, the number and placement of the retainers 220 and locking edges 315 match one another.

The chuck assembly 200 also includes a support pad 235 that sits on the chuck body (center body) 210. As described herein, the support pad 235 is formed of a flexible material and is sufficiently elastic to flex the due to permit metal cleaving without de-bonding to the adhesive film 130. As shown, the support pad 235 can be disk-shaped and is configured to seat against the chuck body 210.

As mentioned, the chuck body 210 holds the saw frame 310 by its outer (peripheral) edge and provides support to the substrate 120 on the chuck body 210 and the support pad 235 that sits upon the chuck body 210. The dicing saw frame 310 is locked in place by retainers 220 that have a bottom support to hold the dicing saw frame 310, and therefore the substrate 120, at a specific height. The retainers 220 are comprised of a radius that attaches the chuck body 210 to the retainer 220. The adhesive 130 under the substrate 120 may contact the support pad 235 but it has been found advantageous for certain metals and thicknesses of backmetal for the wafer (substrate) 120 to be up to 0.050 inches above the support pad 230. Typically, the substrate 120 is supported by the pad 235 and this is important as the plasma has cut the wafer 20 into a group of die held together only by a film of metal. The support pad 235 can vary in thickness and elasticity from application to application, depending on backmetal thickness and composition.

Inside the spin chamber the cleaving process starts by the chamber door closing, so as to contain any fluid dispenses within the processing chamber. Once the door closes the chuck body 210 will begin to rotate to a specified rpm (or sequence of rpm steps). Deionized water from its source, such a carbonator outlined in U.S. Ser. No. 62/081,775, filed Nov. 14, 2014 (which is hereby incorporated by reference in its entirety), will feed low resistivity DI water to an array of dispenses located with the spin chamber. The low resistivity DI:CO2 mixture is required as not to build electrostatic discharge (ESD) that can damage electrical circuits on the die. Low pressure dispenses such as stream and fan spray serve to rinse the substrate. Moderately aggressive dispenses, such as low end high velocity spray (HVS) or minimum pressure\maximum height high pressure dispenses (HPC) will serve to cleave moderate thickness backmetal. Cleaving thick backmetal requires the most aggressive processes such as max pressure HVS 201 and max pressure\min height HPC fan spray 202. The most difficult cleans require the HPC needle dispense 203.

DI 304 water and gaseous carbon dioxide 305 are fed into a carbonator vessel 300 to form lower resistivity water 306 to 200 KOhm/cm and held within tight tolerances. For the most aggressive process this is the feed to the high pressure pump 301. Pumped fluid at 3,000 psi max is fed onto a dispense arm 302 inside the spin chamber. Fluid is released through a dispense nozzle 303. The nozzle is selected based on desired flow rate and pattern (most common are fan and needle. An arm with 2 nozzles is the most common setup. While the substrate spins the arm scans across the chamber. Recipe variables include: chuck rpm, scan speed, acceleration, scan start, scan stop, linear\hyperbolic motion of the arm, nozzle height, nozzle type, pressure, resistivity of DI:CO2 mixture, time and temperature. Any parameter can be adjusted in each step with no practical limit to the number of steps in a particular recipe. These parameters are fine tuned to obtain a clean cleave within a reasonable time frame and without compromising the integrity of the die or removing any die from the adhesive film it is mounted on.

As described herein, the system 100 of FIGS. 1-5 is particularly suited for performing a metal cleaving operation. As described herein, after a plasma dicing operation has been performed, it is desirable to cleave thin metal films that still remain on the semiconductor substrate. As described herein, it is desirable for the substrate to be able to flex during such cleaving operation for the reasons described herein. Since the substrate 120 is located across the center hole of the saw frame 310, the substrate 120 can flex. The substrate 120 is positioned over the support pad 235 and therefore, when the cleaving operation is performed, the substrate 120 can flex and can contact the support pad 235 which in accordance with the present invention, has flexibility to permit the metal cleaving of the thin metal films post plasma dicing.

The support pad 235 can be formed of any number of materials that provide the desired degree of flexing/conformability. For example, the support pad 235 can be formed of a foam material, such as a conformable water-resistant foam (e.g., vinyl foam). This conformable water-resistant foam can have an adhesive backing that permits attachment to the spin chuck body 210. In one exemplary embodiment, the support pad 235 is formed of closed cell vinyl foam that has a thickness of 3/16″ and has a conformable foam construction (e.g., pressure to compress 25% is a load of 2.5 psi). The top surface of the foam has an ultra-smooth texture.

The present invention thus relates to an apparatus and method that employs a pressurized DI spray to cleave metal films on semiconductor substrates post plasma dicing.

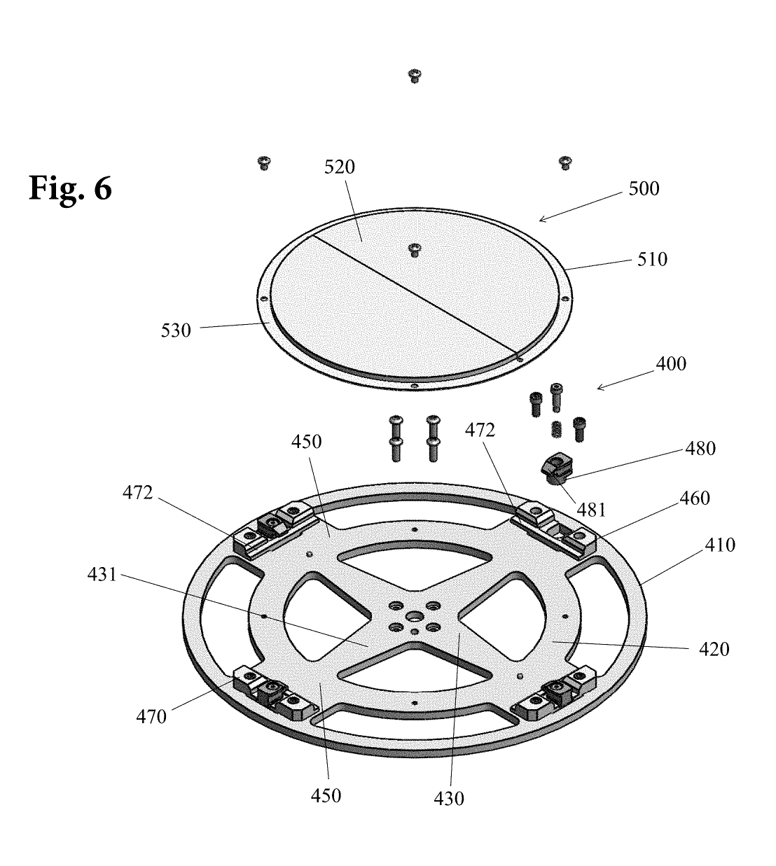

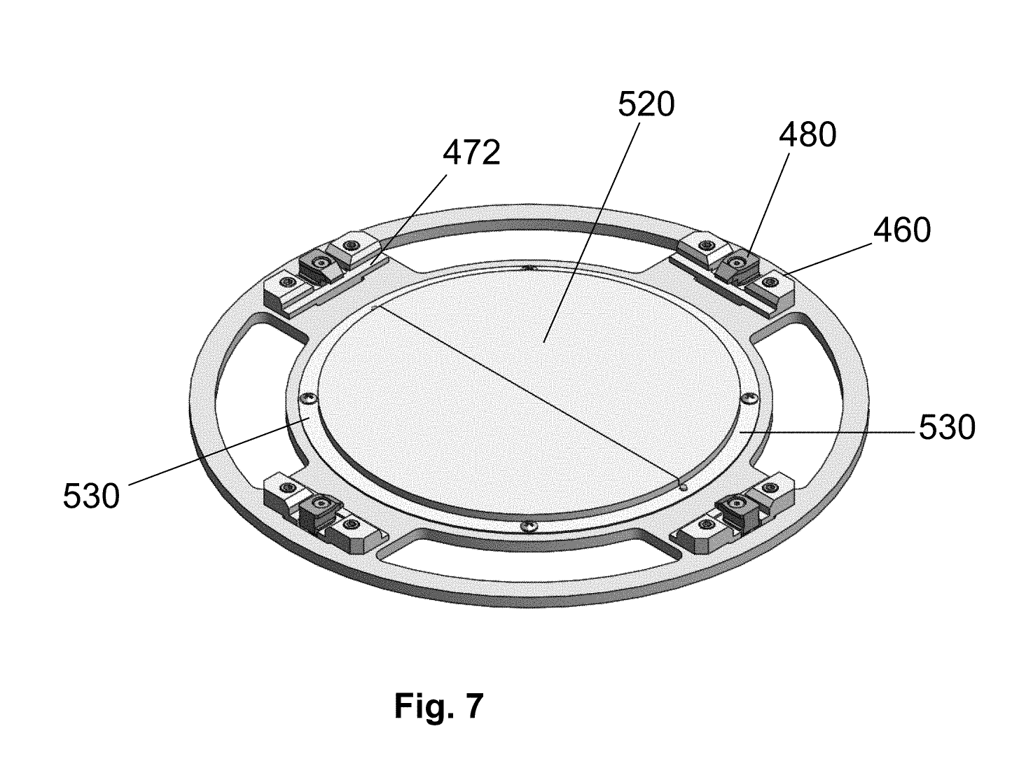

FIGS. 6 and 7 show a chuck assembly 400 according to yet another embodiment. The chuck assembly 400 function essentially in the same manner in which chuck assembly 200 functions in that it retains the saw frame 310 and includes a support pad 500. The use of a flexible pad underneath the wafer (which is part of the saw frame assembly) permits flexing of the wafer to allow cleaving of thin metal films on the diced wafer.

The chuck assembly 400 includes a base 410 that includes a number of openings formed therein so as to define different internal portions of the base 410. More particularly, the base 410 can be thought of as being a wheel shaped structure defined by a center wheel that has an inner annular shaped platform 420 with a cross-shaped spoked structure 430 disposed within the center hole of the inner annular shaped platform 420 and integrally connected thereto. The cross-shaped spoked structure 430 can thus be defined by a plurality of spokes and in the illustrated embodiment, there are four spokes 431 that extend from a center to an inner edge of the inner annular shaped platform 420. The four spokes 431 are oriented 90 degrees apart from one another. The center includes a number of holes to receive fasteners for mounting various components. The inner annular shaped platform 420 also includes a number of holes for receiving fasteners, such as bolts, to allow a part to be attached thereto as described herein. As illustrates, the holes can be defined as a first set that is located along one half of the inner annular shaped platform 420 and a second set that is located along the other half of the inner annular shaped platform 420.

The chuck assembly 400 also includes an outer annular shaped platform 440 that is disposed outside of the inner annular shaped platform 420 such that the outer annular shaped platform 440 surrounds the inner annular shaped platform 420. As shown, the inner annular shaped platform 420 is connected to the outer annular shaped platform 440 by a series of integral connectors or legs 450 that extend radially outward from the inner annular shaped platform 420. As shown, the outer annular shaped platform 440 can have a width less than a width of the inner annular shaped platform 420. The spokes 431 and the legs 450 can be axially aligned as illustrated.

As described and according to one embodiment, the saw frame, although round in shape, has flats cut at every 90 degree. These flats are an optimal location to firmly grab the frame. The frame and wafer will be spun dry. If the saw frame is not held firmly all the force associated with a metal frame spinning at, for example, 2000 rpm would stress the wafer/adhesive film. Accordingly, the ring is supported by the chuck and the wafer is supported by the chuck.

The chuck assembly 400 includes a plurality of retainers 460 that serve to attach the saw frame assembly 300 to the chuck assembly 400. The retainers 460 are thus configured to engage the saw frame 310 (FIG. 1) and in particular, the locking edges 315 thereof. Each retainer 460 is located within one leg 450 that connects the inner and outer annular shaped platforms 420, 440. The retainer 460 includes a retainer frame 470 that has a step 472 (shoulder). The retainer frame 470 can be mounted to the leg 450 using conventional techniques, such as fasteners. As shown, the retainer frame 470 includes a center hollow space that receives a wafer frame clamp 480. A shoulder screw 482 and spring 484 are used to attach the wafer frame clamp 480 to the retainer frame 470. The spring can generate a biasing force and permit the clamp 480 to be biased so as to generate a retaining force against the saw frame assembly so as to keep the saw frame assembly securely in place on the chuck assembly during operation. The wafer frame clamp 480 has a radially extending protrusion 481 that represents an overhang and can be disposed over the top surface of the saw frame 310 so as to clamp the saw frame 310 in place to the chuck assembly 400. If the saw frame assembly is not held firmly, all the force associated with a metal frame spinning at, for example, 2000 rpm would stress the wafer/adhesive film. Accordingly, the ring is supported by the chuck and the wafer is supported by the chuck. When a wafer frame clamp 480 is used, this is permit clamping of the saw frame assembly to the chuck assembly. Other techniques can be used to clamp the saw frame assembly to the chuck assembly.

The support pad 500 includes an annular (ring) shaped base 510 that is configured to allow the support pad 500 to be coupled to the inner annular shaped platform 420. The support pad 500 also includes a center pad 520 that is coupled to the annular shaped base 510 such that the center pad 520 extends across the center hole formed in the annular shaped base 510. The diameter of the annular shaped base 510 is therefore greater than a diameter of the center pad 520 so as to define a circumferential rim portion 530 that extend circumferentially about the center pad 520. The circumferential rim portion 530 includes a number of holes to permit fasteners to pass therethrough. In particular, the annular shaped base 510 is disposed on the upper surface of the inner annular shaped platform 420 with the holes formed in the circumferential rim portion 530 aligning with the holes formed in the inner annular shaped platform 420. Fasteners pass therethrough to couple and attach the support pad 500 to the inner annular shaped platform 420. In this mounted position, the center pad 520 is disposed over the first set of openings formed between the spokes 431.

As with the prior embodiment, the support pad 500 is positioned for alignment with the wafer that is carried in the saw frame assembly 300 and therefore, the retainers 460 surround and are located outside of the support pad 500.

It will be appreciated that the support pad 500 can be identical or similar to the support pad 235 and therefore, it can be formed of a conformable water-resistant foam (e.g., vinyl foam). The support pad 235 can be adhered to the chuck body using a backside adhesive film.

As with the previous embodiment, when the saw frame assembly 300 is coupled (clamped) to the chuck assembly, the wafer 320 is placed in contact with the support pad 500 or can be slightly spaced therefrom as mentioned above. The flexibility of the support pad 500 thus accommodates the movement of the wafer during the metal cleaving operation as described with reference to the previous embodiment.

Notably, the figures and examples above are not meant to limit the scope of the present invention to a single embodiment, as other embodiments are possible by way of interchange of some or all of the described or illustrated elements. Moreover, where certain elements of the present invention can be partially or fully implemented using known components, only those portions of such known components that are necessary for an understanding of the present invention are described, and detailed descriptions of other portions of such known components are omitted so as not to obscure the invention. In the present specification, an embodiment showing a singular component should not necessarily be limited to other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The foregoing description of the specific embodiments will so fully reveal the general nature of the invention that others can, by applying knowledge within the skill of the relevant art(s) (including the contents of the documents cited and incorporated by reference herein), readily modify and/or adapt for various applications such specific embodiments, without undue experimentation, without departing from the general concept of the present invention. Such adaptations and modifications are therefore intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one skilled in the relevant art(s).

While various embodiments of the present invention have been described above, it should be understood that they have been presented by way of example, and not limitation. It would be apparent to one skilled in the relevant art(s) that various changes in form and detail could be made therein without departing from the spirit and scope of the invention. Thus, the present invention should not be limited by any of the above-described exemplary embodiments, but should be defined only in accordance with the following claims and their equivalents.

What is claimed is:

1. An apparatus to improve plasma dicing and a backmetal cleaving process on a substrate that is mounted on an adhesive film, comprising:
a rotatable chuck assembly including a chuck body having a mount portion defined by a first surface, at least two retainers that are spaced apart from one another and are coupled to the chuck body and radially surround the mount portion, each retainer including a retaining edge, wherein the rotatable chuck assembly further includes a flexible chuck support pad that is attached to the first surface of the mount portion of the chuck body; and
a saw frame assembly including a saw frame body that is configured to be disposed and held between the at least two retainers, the saw frame body having at least two locking edges that are configured to seat against the retaining edges of the at least two retainers, the saw frame body being configured to receive the substrate mounted on the adhesive film.

2. The apparatus of claim 1, wherein each retainer is connected to the chuck body by an arm that is attached to an underside of the chuck body and spaces the retainer a predetermined distance from a peripheral edge of the chuck body and the retaining edge of the retainer faces the peripheral edge.

3. The apparatus of claim 2, wherein the retainer comprises a block with a step formed therein, the step defining the retaining edge.

4. The apparatus of claim 2, wherein the arm is configured to be mounted to the chuck body in one of a plurality of predefined positions, wherein for each predefined distance, the retainer is spaced a predetermined distance from the peripheral edge.

5. The apparatus of claim 1, wherein the retaining edge is a linear shaped edge and the locking edge of the saw frame body is a linear shaped edge such that the retaining edge and the respective locking edge seat flush against one another.

6. The apparatus of claim 1, wherein the chuck body includes an inner annular shaped platform that defines at least in part the mount portion and an outer annular shaped platform that is connected to the inner annular shaped platform by a plurality of connector portions, wherein each retainer is disposed on one of the connector portions.

7. The apparatus of claim 6, wherein there are four connector portions oriented 90 degrees apart from one another and there are four retainers oriented 90 degrees apart from one another.

8. The apparatus of claim 6, wherein a spoked structure is formed within a center opening of the inner annular shaped platform, the spoked center extending from a center of the center opening to the inner annular shaped platform.

9. The apparatus of claim 1, wherein the saw frame body is annular shaped except that the at least two locking edges are flats formed along a peripheral edge of the saw frame body.

10. The apparatus of claim 1, wherein the at least two retainers are oriented directly opposite one another and the at least two locking edges formed in the saw frame body are oriented directly opposite one another.

11. The apparatus of claim 1, wherein there are four retainers oriented 90 degrees apart from one another and there are four retaining edges oriented 90 degrees apart from one another and four locking edges oriented 90 degrees apart from one another.

12. The apparatus of claim 1, wherein the flexible chuck support pad has a disc shaped.

13. The apparatus of claim 1, wherein the flexible check support pad comprises a conformable foam pad.

14. The apparatus of claim 13, wherein the conformable foam pad comprises a conformable vinyl foam pad.

15. The apparatus of claim 1, wherein the saw frame body is held between the at least two retainers by one of a friction fit and by one or more clamps.

16. The apparatus of claim 1, wherein heights of the at least two retainers and a thickness of the flexible chuck support pad are selected such that when the saw frame assembly is mounted to the chuck assembly, the saw frame body contacts the flexible chuck support pad.

17. The apparatus of claim 1, wherein the substrate is positionable up to 0.050 above the flexible chuck support pad.

18. The apparatus of claim 1, wherein the flexible chuck support pad has elasticity to permit the substrate to flex when a sufficient load is applied thereto without debonding of the adhesive film relative to the substrate.

19. The apparatus of claim 1, wherein the flexible chuck support pad has elasticity to permit damping of a pressurized fluid flow allowing cleaving of metal films on the substrate without damage to the metal or die or to prematurely remove die off an adhesive material to which the substrate is adhered.

20. The apparatus of claim 1, wherein the substrate has a backmetal layer and a thickness and elasticity of the flexible chuck support pad is selected in view of a thickness and composition of the backmetal layer.
